(19) United States
(12) Patent Application Publication
(10) Pub. No.: US 2021/0391803 A1
(43) Pub. Date: Dec. 16, 2021

(54) MODULAR IN-WALL AC-DC POWER SUPPLY

(71) Applicant: Vigil Tech, Inc., Colorado Springs, CO (US)

(72) Inventors: John Matthew Martinez, Colorado Springs, CO (US); Jonathan Thompson, Colorado Springs, CO (US)

(21) Appl. No.: 17/344,175

(22) Filed: Jun. 10, 2021

Related U.S. Application Data
(60) Provisional application No. 63/038,322, filed on Jun. 12, 2020.

(51) Int. Cl. H02M 7/155; H02H 7/12

(52) U.S. Cl. CPC H02M 7/1555; H02H 7/12

(57) ABSTRACT

Various embodiments of the present technology relate to power supplies and interchangeable modules coupled with power supplies used to control a load. In operation, a switch assembly includes two components: a power supply module and a removable module, which function to convert AC to DC to provide input modularity and enhanced control of the input and load. The power supply module comprises AC circuitry configured to convert an AC signal to DC. The power supply module also comprises an interface coupled with the removable module and logic circuitry configured to control an aspect of a load based on an indication from input devices of the removable module. The removable module comprises a communication interface configured to provide the indication from the input devices to the logic circuit via the interface. Also, the removable module comprises DC circuitry to provide power to the removable module.

### CROSS-REFERENCE TO RELATED APPLICATIONS

The present application claims priority to U.S. Provisional Application No. 63/038,322 filed Jun. 12, 2020 titled “Universal In-Wall AC Switch and DC Power Supply” which is incorporated herein by reference in its entirety for all purposes.

### TECHNICAL FIELD

Various embodiments of the present technology relate to modular power supply assemblies and systems and devices for converting AC mains to a desired output for universal use with DC electronic devices.

### BACKGROUND

Alternating Current (AC) is a remnant of the previous century when AC became established as the dominant electrical infrastructure throughout the world due mainly to its transmissibility. Unlike Direct Current (DC) at the time, AC could be transmitted hundreds of miles allowing for the separation of power generation from the point of consumption in homes, buildings, and other structures. As AC became the de facto electricity standard, and this led to the creation of devices and appliances, for example lights, motors, and refrigerators that are powered by AC. Nearly all of the world's electrical infrastructure became powered by AC with the majority of electricity consuming appliances and devices being electro-mechanical in nature.

The advent of the semiconductor and the rise of solid-state electronics led to a multitude of new digital devices becoming available that cannot use AC. For example, LCD televisions, alarm clocks, wireless phones, and computers require DC. The new universe of Direct Current devices and appliances, unless battery powered, must receive DC. Since buildings receive AC from utilities, the AC must be converted to DC for these newer devices and appliances. To date, the predominant method for DC-powered devices to receive DC is for the device itself to have an AC to DC conversion circuit. Power cords for laptop computers, for example, usually come with a brick-like object that performs conversion.

For in-wall devices like capacitive touch wall switches, the AC to DC conversion circuit is built into the switch itself. For DC powered devices like computers that plug into a wall outlet socket, there is usually the aforementioned brick with a cord that converts the AC to the necessary DC, for example 24 Volt, 12 Volt, or 5 Volt that the device or appliance requires. Further, for in-wall DC devices that have embedded AC to DC conversion circuits like smart switches, touchscreen wall stations, occupancy sensors, video cameras, and voice assistants, whenever the device needs to be replaced, a certified electrician is required to replace the device due to the device's usage of AC mains power.

Companies that sell products that use mains AC must certify the safety of those products with an accredited test organization. Assurance, Inspection and Product Testing organizations like Underwriters Labs (UL), Canadian Standards Association (CSA) and Intertek certify products. These certifications are expensive and must be maintained through payment of ongoing annual fees that include on-site factory inspections at manufacturing facilities. Building codes require devices and appliances that directly connect to AC be certified by one of the accredited testing organizations. In most cases, in order to file an insurance claim, fire insurers require proof that all products installed were certified by one of the accredited test organizations.

### OVERVIEW

A modular switch assembly is disclosed herein that provides a DC output from an AC power supply module to a removable module to allow for modularity and control of a DC interface coupled with an AC load. The modular switch assembly includes two components: a power supply module and a removable module. The power supply module comprises AC circuitry configured to convert an AC signal (i.e., AC mains) to DC. The power supply module also comprises an interface coupled with the removable module and a logic circuit configured to control an aspect of an AC load based on an indication from one or more input devices of the removable module. The removable module comprises the one or more input devices and a communication interface configured to provide the indication from the input devices to the logic circuit via the interface. Also, the removable module comprises DC circuitry to provide power to the removable module. Further, for enhanced safety, a line-break plunger is included that terminates connection to the AC signal whenever the removable module is disconnected from the power supply module. This allows an end-user to at least circumvent use of a certified electrician to replace or reconfigure the module and avoid electrical touch risks.

In an embodiment, a system comprising a power supply module and a removable module is included. The power supply module includes one or more DC ports, one or more low-voltage control ports, an AC-to-DC transformer, and a line-break plunger. The AC-to-DC transformer is fed by an AC line and is configured to convert the AC line to DC power for use by the one or more DC ports. The removable module can be operatively coupled with the power supply module by connecting one or more DC inputs to the one or more DC ports and one or more low-voltage control inputs to the one or more low-voltage control ports of the in-wall power supply. When the two devices are coupled, the line-break plunger is engaged and enables a connection between the AC line and the AC-to-DC transformer allowing the removable module to be powered on to control an aspect of a load connected to the system.

This Overview is provided to introduce a selection of concepts in a simplified form that are further described below in the Detailed Description. This Overview is not intended to identify key features or essential features of the claimed subject matter, nor is it intended to be used as an aid in determining the scope of the claimed subject matter.

While multiple embodiments are disclosed, still other embodiments of the present technology will become apparent to those skilled in the art from the following detailed description, which shows and describes illustrative embodiments of the invention. As will be realized, the technology is capable of modifications in various aspects, all without departing from the scope of the present invention. Accordingly, the drawings and detailed description are to be regarded as illustrative in nature and not restrictive.

### BRIEF DESCRIPTION OF THE DRAWINGS

Embodiments of the present technology will be described and explained through the use of the accompanying drawings in which:

FIGS. 1A and 1B illustrate exemplary operating architectures of a power converter in accordance with some embodiments of the present technology;

FIG. 2 illustrates an exemplary control interface of a power converter in accordance with some embodiments of the present technology;

FIGS. 3A and 3B illustrate exemplary power supplies using wireless power transfer in accordance with some embodiments of the present technology;

FIG. 4 is a flowchart illustrating an exemplary process for operating an in-wall switch with removable modules in accordance with some embodiments of the present technology;

FIGS. 5A and 5B illustrate exemplary power supply and switch systems in accordance with some embodiments of the present technology; and

FIG. 6 illustrates an exemplary power supply and switch using wireless power transfer in accordance with some embodiments of the present technology.

The drawings have not necessarily been drawn to scale. Similarly, some components and/or operations may be separated into different blocks or combined into a single block for the purposes of discussion of some of the embodiments of the present technology. Moreover, while the technology is amenable to various modifications and alternative forms, specific embodiments have been shown by way of example in the drawings and are described in detail below. The intention, however, is not to limit the technology to the particular embodiments described. On the contrary, the technology is intended to cover all modifications, equivalents, and alternatives falling within the scope of the technology as defined by the appended claims.

### DETAILED DESCRIPTION

Various embodiments of the present technology relate to power supplies and interchangeable modules coupled with power supplies used to control one or more loads. In operation, a modular switch assembly includes two components: a power supply module and a removable module, which function to convert AC power to DC power for interface modularity and enhanced control of the input and loads. The power supply module comprises AC circuitry configured to convert an AC signal (i.e., AC mains) to DC. The power supply module also comprises an interface coupled with the removable module and a logic circuit configured to control an aspect of an AC load based on an indication from one or input devices of the removable module. The removable module comprises the one or more input devices (i.e., switch, dimmer, button, touchscreen) and a communication interface configured to provide the indication from the input devices to the logic circuit via the interface. Also, the removable module comprises DC circuitry to provide power to the removable module. Further, for enhanced safety, a line-break plunger is included that terminates connection to the AC signal whenever the removable module is disconnected from the power supply module. This allows an end-user to remove, replace, change, or upgrade the removable module without shutting off source power. This may circumvent the use of a certified electrician to replace or reconfigure the module and avoid electrical touch risks.

Another embodiment provides for a system comprising a power supply module and a removable module. The power supply module includes one or more DC ports, a controller, an AC to DC transformer, and a line-break plunger. The AC to DC transformer is fed by an AC line and is configured to convert the AC line to a DC power source for use by the one or more DC ports. The removable module, such as a faceplate, switch, touchscreen, and the like, can be operatively coupled with the power supply module. When the modules are coupled, the line-break plunger on the power supply module enables a connection between the AC line and AC circuitry allowing current flow to power the system.

In yet another embodiment, a power supply module comprises an AC to DC transformer configured to convert power from an AC line, such as a grid power source, to consumer-electronic usable DC power. DC ports on the power supply module are coupled with DC inputs of a removable module, such as a faceplate or switch. Additionally, low-voltage control ports of a controller are coupled to low-voltage inputs of a module to provide communications control, dimming control, and other interfacing. For end-user safety, the power supply module further comprises a line-break plunger that functions to provide an air gap for the circuitry. Without the removable module attached to the power supply module, the line-break plunger can remain in an open position terminating any connection between the AC line and the power supply module. This allows an end-user to configure module inputs to power supply module ports without shutting off the source power (i.e., AC mains). Upon connecting a module, the line-break plunger can be engaged and complete the circuit to provide power to the removable module and allow control of a load connected to the system.

Advantageously, manufacturers can develop in-wall electronic devices without having to design an AC power supply, concerning themselves with AC to DC power conversion or other constraints, or certifying each product with an accredited test organization (i.e., UL, CSA, Intertek) as the technology herein can allow for user manipulation of a removable faceplate device that uses SELV DC without changing AC circuitry. Thus, only the electronic device or module may need to be configured appropriately to adapt the use of the DC power provided by the power supply module. For example, a module that requires 12V DC can be connected to the power supply accordingly. Then, if a further module requires a lower or higher DC voltage, the first module can be removed, and the further module can be configured to use the appropriate voltage without altering the power supply or power source. Additionally, the appropriate or expected power level can be monitored to ensure correct configuration of the power supply and/or loads for safety and diagnostic capabilities.

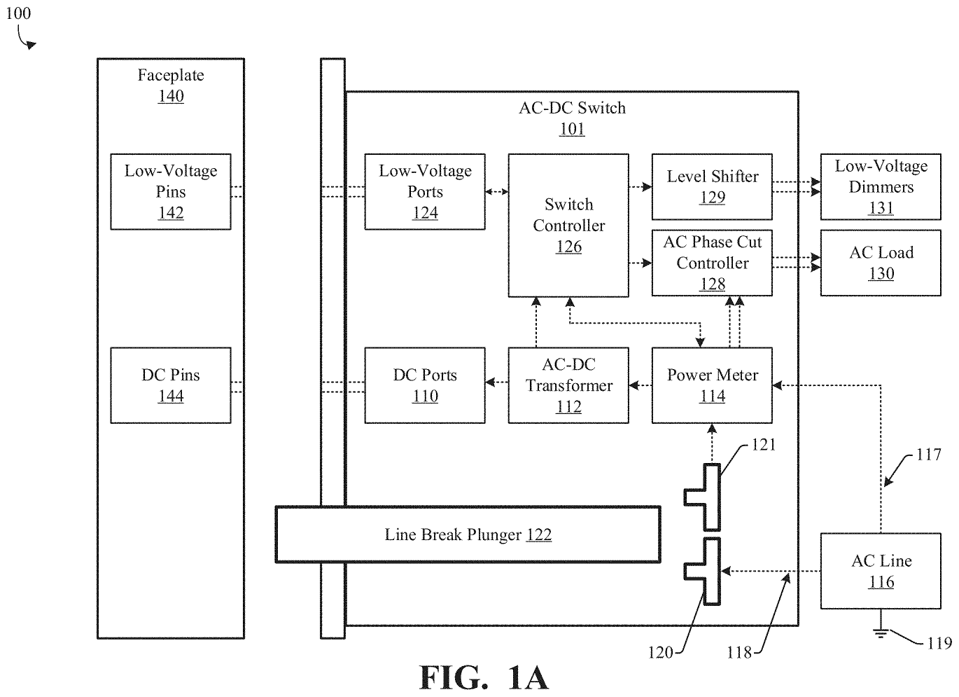

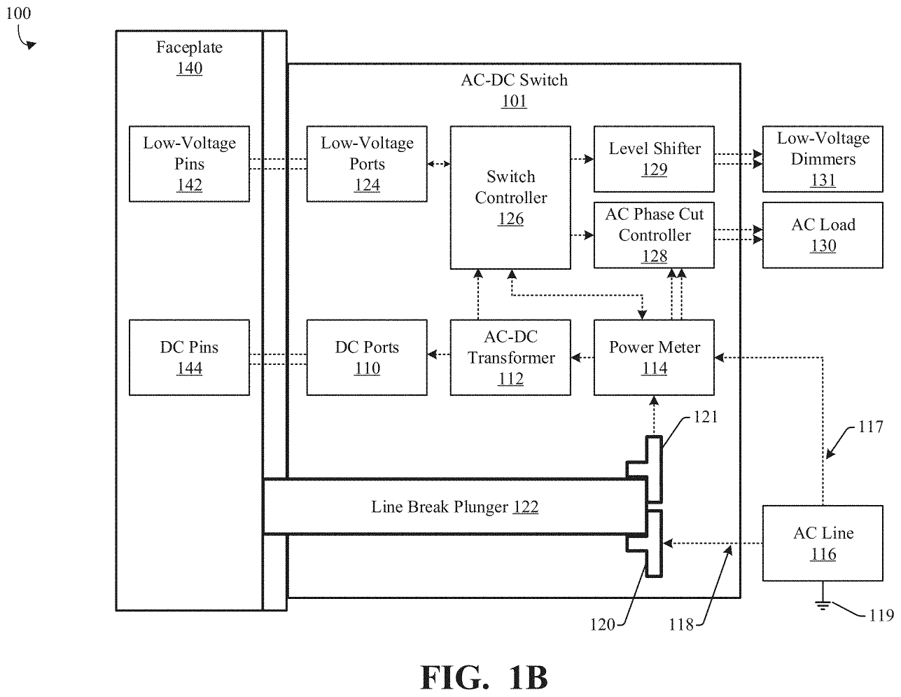

Turning now to the Figures, FIGS. 1A and 1B illustrate aspects of an exemplary operating architecture 100 which include a power supply module and a removable faceplate module in accordance with some embodiments of the present disclosure. Operating architecture 100 demonstrates a faceplate 140 that can be operatively coupled with and removed from AC-DC switch 101. AC-DC switch 101 further includes DC ports 110, AC-DC transformer 112, power meter 114, contacts 120 and 121, line break plunger 122, low-voltage ports 124, switch controller 126, AC phase cut controller 128, and level shifter 129. AC-DC switch 101 is fed AC power by AC line 116 via AC hot wire 118, an AC neutral wire 117, and AC ground wire 119. Also, AC-DC power supply 101 can send an output to AC load 130 and low-voltage dimmers 131. Faceplate 140 includes a removable module with inputs or couplings as demonstrated by low-voltage pins 142 and DC pins 144.

AC-DC switch 101 can generate direct current (DC) electricity from AC line voltage providing a standardized connector interface for a DC power supply. The DC power can be transferred from the DC power supply to an electronic device through connector pins/ports, thus allowing modularity and control of the electronic device that connects to AC-DC switch 101. More specifically, AC line 116 provides power to AC-DC switch 101 over AC hot wire 118, AC neutral wire 117, and AC ground wire 119. The AC hot wire 118 connects to contact 120, which may be located on or inside AC-DC switch 101. Each of contacts 120 and 121 can be made conductive materials to allow electricity to flow through the circuit when line break plunger 122 is engaged and the circuit between the two contacts is complete. The AC power provided to AC-DC switch 101 feeds power meter 114 for monitoring, among other things, and AC-DC transformer 112 for converting power from AC to DC for use by a DC module, such as faceplate 140.

Power meter 114 provides measurements of power and energy for the system. For example, power meter 114 can deliver real-time voltage and current waveforms, calculate root mean square (RMS) values of voltage and current (i.e., sag and swell), active, reactive, and apparent power and energy, total harmonic distortion, power factor, and the like. In various instances, power meter 114 can be used to display metrics on a user interface or application for an electrician or other user to perform diagnostics on the power supply. With respect to safety considerations, power meter 114 can be configured to monitor for overvoltage or overcurrent conditions. Power meter 114 and switch controller 126 can be operatively coupled and can communicate bidirectionally to ensure proper circuit design and functionality, prevent overloading, and monitoring of performance, among other things. In an instance, switch controller 126 can receive an indication of overvoltage from power meter 114, and in response, switch controller 126, at a configurable time, can turn off one or more downstream loads to prevent system failure and/or damage to the downstream loads.

Following power meter 114, AC power can flow to AC-DC transformer 112 and AC phase cut controller 128. AC-DC transformer 112 can convert AC line voltage to DC and provide a DC output to be used by an electronic device or module, such as faceplate 140, via DC ports 110. In some embodiments, AC-DC transformer 112 is a transformer, although in other embodiments, it could be a rectifier, AC-to-DC converter, or the like. Accordingly, DC ports 110 receives DC from AC-DC transformer 112 including a 12V line and a reference line to ground an electrical current. It may be appreciated that AC-DC transformer 112 can provide different levels of voltage to DC ports 110 in other instances.

AC-DC transformer 112 can also provide a DC output to power switch controller 126. Switch controller 126 can comprise a collection of pins that can be configured to receive low-voltage signals from low-voltage ports 124 to control aspects of AC load 130 and/or low-voltage dimmers 131. AC load 130 can be a light, fan, speaker, sensor, or other device, which can be powered on/off and otherwise controlled via the modular system including AC-DC switch 101 and faceplate 140. To provide control and interfacing with such a device, low-voltage ports 124 comprise one or more input pins or couplings including one or more communication ports, a phase cut triac dimmer port, a 0-10V low voltage dimming port, and a DALI low voltage dimming port, among others. Each dimming port can provide control of a dimmer switch, such as an integrated dimmer, touch screen dimmer, and the like by communicating signals to a load via switch controller 126.

Switch controller 126 can communicate low-voltage signals to either or both of AC phase cut controller 128 and level shifter 129 based on a command sent over a coupling with faceplate 140. For example, if AC load 130 is a phase cut dimmer, such as a radial dimmer, AC phase cut controller 128 can be configured to cut the AC phase of a signal sent from AC line 116 through power meter 114. Alternatively, when using different dimming protocols, such as DALI or 0-10V dimming, switch controller 126 can route signals from low-voltage ports 124 to level shifter 129 to provide control of one or more low-voltage dimmers 131. It may be appreciated that switch controller 126 can have bi-directional communications with power meter 114 to allow for digital display of power consumption of a system. It may also be appreciated that switch controller 126 can allow for wireless communications between a faceplate 140 and one or more loads connected to AC-DC switch 101.

In the disconnected configuration shown in FIG. 1A, line break plunger 122 of AC-DC switch 101 rests in a normally-open position leaving the AC power supply circuit open. Line break plunger 122 can be a spring-loaded pin, a pressurized pin, or some other apparatus that automatically recedes from contacts 120 and 121 to open the circuit between AC line 116 (i.e., AC hot wire 118) and AC-DC transformer 112 when faceplate 140 is removed. As a result of breaking this circuit, DC ports 110, switch controller 126, and AC phase cut controller 128 receive no current, so AC-DC switch 101 and respective ports can be touched, reconfigured, and the like without risk of an electrical shock.

In FIG. 1B, a configuration of operating architecture 100 is shown wherein faceplate 140 is operatively coupled to AC-DC switch 101. Faceplate 140, such as a switch, dimmer, thermostat, touchscreen, or some other switch or smart device, can be a removable module allowing for a variety of configurations and uses of the system in operating architecture 100. Faceplate 140 is now connected with AC-DC switch 101 by inputs or couplings as demonstrated by low-voltage pins 142 and DC pins 144.

In operation, DC pins 144 can be coupled or connected to DC ports 110 of AC-DC switch 101 and low-voltage pins 142 can be coupled to low-voltage ports 124. However, power may not flow through the ports until line break plunger 122 is depressed into AC-DC switch 101 to close the circuit. When line break plunger 122 reaches contacts 120 and 121, current can flow from AC line 116 through power meter 114 and further to AC-DC transformer 112, among other parts of the circuitry. In various embodiments, DC pins 144 can receive 12V DC or some other voltage to power an electronic device embodied in faceplate 140. Low-voltage pins 142 can be mapped to communication and control ports to provide interfacing capabilities mentioned above.

It may be appreciated that faceplate 140 can be removed, reconfigured (i.e., use of various low-voltage ports 124), and reattached to provide modularity of a system and control of different loads. Further, AC-DC switch 101, and modules coupled with it, can be used in a no-neutral configuration in cases where a neutral line is nonexistent in the in-wall electrical wiring. To do so, a dummy load may be included in the circuitry to mimic a design that includes a neutral wire.

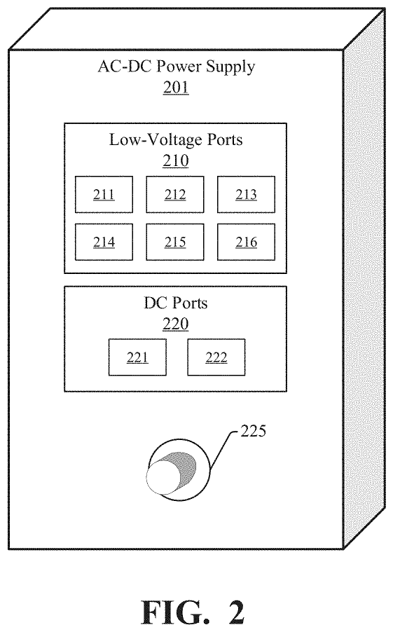

FIG. 2 illustrates an exemplary interface of a power converter in accordance with some embodiments of the present technology. FIG. 2 includes AC-DC power supply 201, low-voltage ports 210, DC ports 220, and line break plunger 225. Low-voltage ports 210 further include ports 211-216. DC ports 220 further includes ports 221 and 222. For example, AC-DC power supply 201 can provide the functionality of AC-DC switch 101 of FIGS. 1A and 1B.

AC-DC power supply 201 may be an in-wall device that provides a DC power source and control interface for a removable, electronic device that can be attached to AC-DC power supply 201, such as faceplate 140 of FIGS. 1A and 1B. AC-DC power supply 201 receives its power from an AC power source such as AC mains. Internally, AC-DC power supply 201 can comprise a metering interface, one or more controllers, and an AC-DC power converter (i.e., a transformer or rectifier), among other components, to convert power from the AC power source into DC electricity to power on a device connected to AC-DC power supply 201 via DC ports 220. DC ports 220 can receive the DC output from the AC-DC power converter, which can be embodied as a DC power line and a reference line in the form of port 221 and 222. In some embodiments, port 221 can provide 12V DC, while in other embodiments the converter can be configured to deliver another DC voltage to DC ports 220. To ensure that AC-DC power supply 201 utilizes the proper voltage, current, and loads, the metering interface coupled with a switch interface can be configured to monitor and control the circuitry and input/output power.

While no device is coupled to AC-DC power supply 201, line break plunger 225 prevents any flow of current from the power source to DC ports 220 among other parts of the circuit. Line break plunger 225 can be a spring-loaded pin, other actuator, or latching switch that remains in a normally open position when AC-DC power supply 201 has no faceplate, module or apparatus, or other interface attached to it. Upon connecting a module to AC-DC power supply 201, line break plunger 225 is depressed into AC-DC power supply 201 and completes a circuit, thus allowing electricity to flow from an AC power source to the AC to DC converter, DC ports 220, low-voltage ports 210, the one or more controllers, and other parts of AC-DC power supply 201.

To allow for bi-directional communication and control between a faceplate or other removable electronic device and a load, low-voltage ports 210 are provided. Low-voltage ports 210 can comprise one or more dimming ports, one or more communication ports, and/or one or more data ports, among other types of low-voltage control ports. In various embodiments, low-voltage ports 210 comprise six ports 211-216, which include a phase cut dimmer port, a 0-10V low-voltage dimmer port, a DALI low voltage dimmer port, and three communication ports, respectively. Each dimmer port can be utilized by a device based on system requirements and objectives. Additionally, if a device uses port 211 for phase cut dimming, a further device that replaces a first equipped device can switch to DALI dimming using port 212, and so on, providing for modularity with AC-DC power supply 201. Each communication port (i.e., ports 214-216) can be used for bi-directional communications with a controller and/or the equipped device to control power levels, radio frequency (RF) devices, and other interfaces. In some instances, each communication port can remain unconnected. It may be appreciated that low-voltage ports 210 can comprise additional or fewer ports in some embodiments. One or more controllers may also be included (not pictured) to provide interfacing with at least AC-DC power supply 201 and one or more loads controllable via low-voltage communications.

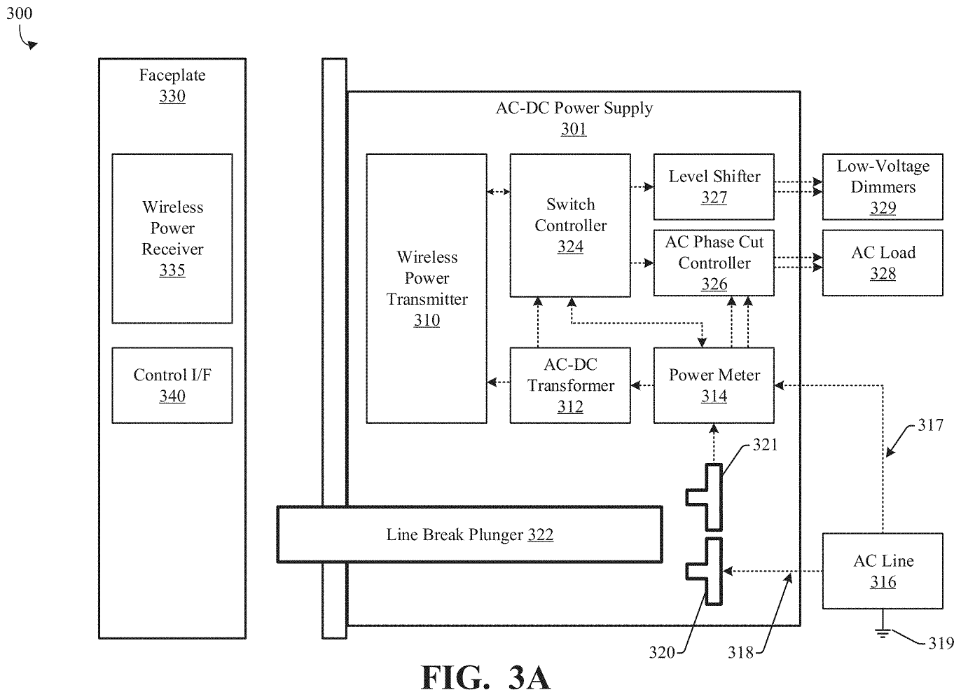

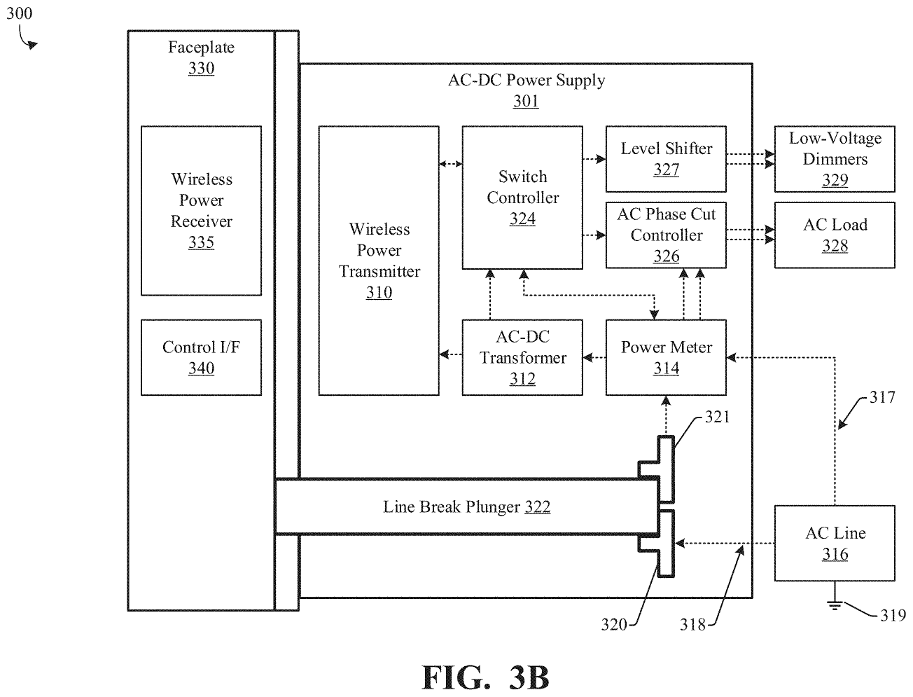

Moving to FIGS. 3A and 3B, FIGS. 3A and 3B illustrate aspects of an exemplary power supply using wireless power transfer in accordance with some embodiments of the present technology. FIGS. 3A and 3B include operating environment 300, which further includes AC-DC power supply 301 and faceplate 330. Operating environment 300 provides for a removable faceplate 330 that can be connected to AC-DC power supply 301 to transfer power wirelessly via a transmitter and receiver configuration. AC-DC power supply 301 includes wireless power transmitter 310, AC-DC transformer 312, power meter 314, contacts 320 and 321, line break plunger 322, switch controller 324, AC phase cut controller 326, and level shifter 327. AC-DC power supply 301 is fed AC power by AC line 316 via AC hot wire 318, AC neutral wire 317, and AC ground wire 319. Also, AC-DC power supply 301 can send an output to AC load 328 and low-voltage dimmers 329. Faceplate 330 includes a removable module that can be coupled with AC-DC power supply 301 via wireless power receiver 335 and control interface 340.

Faceplate 310 and AC-DC power supply 330 can be operatively coupled to create an integrated switch and power supply to control one or more loads, such as a light switch, thermostat, touchscreen, or other smart switch used to control a module. AC-DC power supply 330 can receive power from AC mains, a grid, or other power source to provide power to wireless power transmitter 335. AC line 316 provides power to AC-DC power supply 301 over a switched line, such as AC hot wire 318. AC hot wire 318 can connect to contacts 320 and 321, which may be located on or inside AC-DC power supply 301. Each of contacts 320 and 321 can be made of conductive materials to allow electricity to flow through the circuit when line break plunger 322 completes a circuit between AC load 316 and AC-DC power supply 301. The AC power provided to AC-DC power supply 301 feeds power meter 314 for monitoring, among other things, and AC-DC transformer 312 for converting power from AC to DC for use by a DC module, such as faceplate 330.

Power meter 314 provides measurements of power and energy for the system. For example, power meter 314 can deliver voltage and current waveforms, calculate root mean square (RMS) values of voltage and current, active, reactive, and apparent power and energy, total harmonic distortion, power factor, and the like. In various instances, power meter 314 can be used to display electrical metrics on a user interface for an electrician or other user to perform diagnostics on the electrical system performance. With respect to safety considerations, power meter 314 can be configured to monitor for overvoltage conditions, overcurrent conditions, or excessive loading. Power meter 314 and switch controller 324 can be operatively coupled and can communicate bidirectionally to ensure proper circuit design and functionality, prevent overloading, and monitoring of performance, among other things. In an instance, switch controller 324 can receive an indication of overvoltage from power meter 314, and in response, switch controller 324 can turn off one or more downstream loads to prevent system failure and/or damage to the downstream loads.

AC power can flow to AC-DC transformer 312 and AC phase cut controller 326 following power meter 314. AC-DC transformer 312 can convert AC to DC and provide a DC output to be used by an electronic device or module, such as faceplate 330, via wireless power transmitter 310. In some embodiments, AC-DC transformer 312 is a transformer, although in other embodiments, it could be a rectifier, AC-to-DC converter, or the like. Accordingly, wireless power transmitter 310 receives DC from AC-DC transformer 312 as a 12V source. It may be appreciated that AC-DC transformer 312 can provide different levels of voltage in other instances.

AC-DC transformer 312 can also provide a DC output to power switch controller 324. Switch controller 324 can comprise a collection of pins that can be configured to receive signals from control interface 340 to control aspects of AC load 328 and/or low-voltage dimmers 329. AC load 328 can be a light, fan, speaker, sensor, or other device, which can be powered on/off and otherwise controlled via the modular system including AC-DC switch 301 and faceplate 330. To provide control and interfacing with such a device, switch controller 324 comprise one or more input pins or ports including one or more communication ports, a phase cut triac dimmer port, a 0-10V low voltage dimming port, and a DALI low voltage dimming port, among others, that can be coupled with control interface 340. Each dimming port can provide control of a dimmer switch, such as an integrated dimmer, touch screen dimmer, and the like by communicating signals to a load via switch controller 324.

Switch controller 324 can communicate low-voltage signals to either or both of AC phase cut controller 326 and level shifter 327 based on a command sent over a coupling with faceplate 330. For example, if AC load 328 is a phase cut dimmer, such as a radial dimmer, AC phase cut controller 326 can be configured to cut the AC phase of a signal sent from AC line 316 through power meter 314. Alternatively, when using different dimming protocols, such as DALI or 0-10V dimming, switch controller 324 can route signals to level shifter 327 to provide control of one or more low-voltage dimmers 329. It may be appreciated that switch controller 324 can have bi-directional communications with power meter 314 to allow for digital display of power consumption of a system.

Wireless power transmitter 310 can comprise circuitry including but not limited to an AC-DC power converter, a DC-DC power converter (i.e., a half-bridge or full-bridge converter), one or more transmitter coils, a transmitter control interface, and the like. On or inside faceplate 330, wireless power receiver 335 is configured to receive power emitted from wireless power transmitter 335 over a gap. Wireless power receiver 335 can comprise one or more receiver coils, a receiver control interface, a rectifier, one or more filters, and a battery, among other components.

When faceplate 330 and AC-DC power supply 301 are connected as in FIG. 3B, line break plunger 322 is pushed into AC-DC power supply 301 to close any breaks in internal circuitry, such as between AC hot wire 318 and power meter 314 via contacts 320 and 321, allowing current to flow from AC line 316 to wireless power transmitter 310. Additionally, wireless power transmitter 310 can be aligned with wireless power receiver 335 to allow the two to be configured in proximity such that the transmitter coils and receiver coils sit atop each other. As current flows through wireless power transmitter 310, the one or more transmitter coils can emit energy over a gap which can be received by the one or more receiver coils or wireless power receiver 335. It may be appreciated by one skilled in the art that AC-DC power supply 301 can operate without line break plunger 322 as wireless power transmissions may not have an electrical touch risk when faceplate 330 is removed from contact with AC-DC power supply 301.

Control interface 320 is also included in or on faceplate 330 to provide controls for a smart switch or device. Control interface 340 can be operatively coupled with wireless power receiver 335 to provide power for interfacing. By way of example, one side of faceplate 330 can be a capacitive touch screen for end-user control while the other side can include wireless power receiver 335 and control interface 340 that connect to AC-DC power supply 301. Control interface 340 can be configured to provide dimming control of the touch screen, backlighting of the touch screen, and other controls performable by the touch screen.

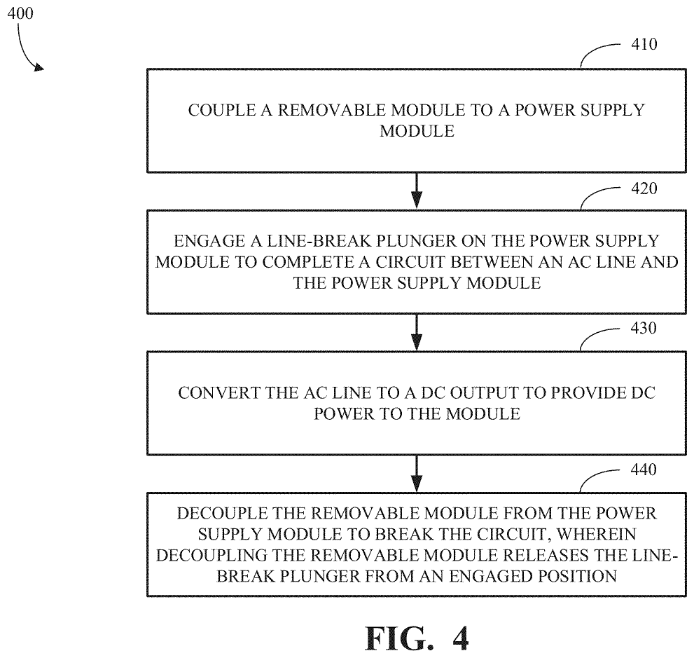

FIG. 4 is a flowchart illustrating an exemplary process for operating a power supply module with removable modules in accordance with some embodiments of the present technology. FIG. 4 includes process 400 which further includes various steps to couple and remove modules from a power supply module. For example, process 400 can be implemented in AC-DC switch 101 of FIGS. 1A and 1B, AC-DC power supply of 201 of FIG. 2, and AC-DC power supply 301 of FIGS. 3A and 3B.

Process 400 first includes coupling 410 a removable module to a power supply module. The removable module can be a detachable, re-configurable, and/or interchangeable faceplate such as a thermostat, lighting control device, touch screen, or the like. The module may be fixed to the power supply module via wiring connections and/or other mechanical fixtures to hold the module in place. To wire together the module and in-wall switch, one or more inputs of the removable module can be coupled to one or more ports of the power supply module. For example, both devices comprise DC power connections and low-voltage control connections which can be connected to provide power and interfacing controls, respectively. It may be appreciated that the switch assembly comprising both modules can be wirelessly coupled and transfer power and communications over wireless connections.

Process 400 next includes engaging 420 a line-break plunger on the power supply module to complete a circuit between an AC line or power source and the power supply module. The line-break plunger can be a spring-loaded pin, latching device or actuator that remains in a normally open position when nothing is coupled to the power supply module. Upon coupling a removable module to the power supply, the line-break plunger can be pressed into one or more conductive plates, which allows current to flow throughout the power supply module. The AC line can be a household or enterprise power source, such as AC mains, that provides power to an outlet or switch.

Process 400 also includes converting 430 the AC line to a DC output to provide DC power to the removable module. In various embodiments, the removable module functions by using DC power rather AC power. Thus, an AC to DC transformer or converter is implemented in the power supply module to generate a DC voltage, such as 12V. The DC power output from the transformer can be routed to the DC ports of the power supply module and further routed to the removable module via DC inputs or pins of the removable module. Additionally, the AC input power can be monitored by a metering apparatus to ensure proper output voltage and current, among other measurements.

Process 400 lastly includes decoupling 440 the removable module from the power supply module to break the circuit. Decoupling the removable module releases the line-break plunger from an engaged position and terminates current flow from the power source or AC line to the power supply module. This provides a safety feature as the ports located on or inside the power supply module no longer have any power connected to them, and they can be safely handled by a user. This allows for reconfiguration of the removable module's inputs or for the attachment of a new module to the power supply module without terminating the power source itself.

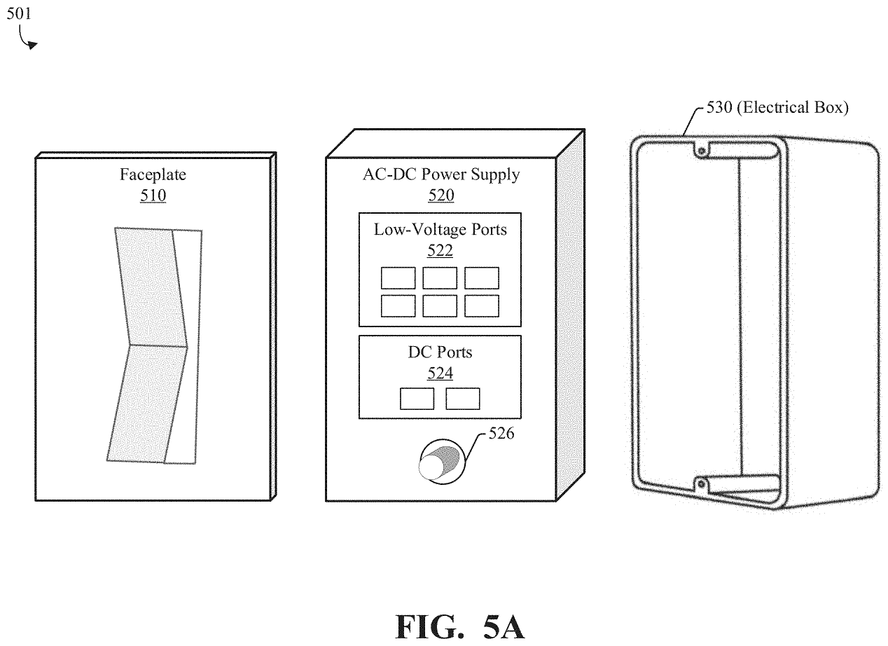

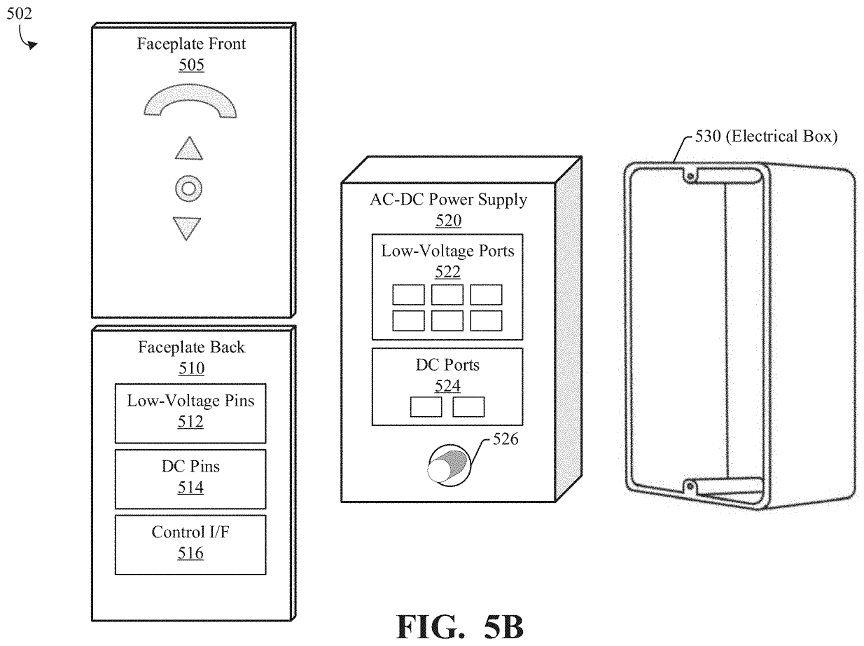

Moving to FIGS. 5A and 5B, each illustrates exemplary DC power supply and AC switch systems. First, FIG. 5A includes system 501, which further includes faceplate 510, AC-DC power supply 520, and electrical box 530. AC-DC power supply 520 further includes low-voltage ports 522, DC ports 524, and line-break plunger 526.

System 501 demonstrates a rocker switch, shown as faceplate 510, that can be coupled with AC-DC power supply 520 and affixed to electrical box 530 that can be secured into a wall or other structure. AC-DC power supply 520 comprises one or more ports as part of low-voltage ports 522 and DC ports 524, each of which can be coupled to one or more inputs of faceplate 510. For example, DC circuitry of faceplate 510 can connect to DC ports 524 to provide DC power to the module embodied in faceplate 510. Further, an interface of faceplate 510 can connect to one or more ports of low-voltage ports 522 to provide control of the module. In the illustrated instance, a rocker switch may use DC ports 524 to control power to a load, such as a light bulb; however, if the rocker switch is accompanied or replaced by a dimmer, low-voltage ports 522 can be utilized to operate dimming capabilities of said light bulb via a control circuit in AC-DC power supply 520.

After coupling inputs of faceplate 510 to ports of AC-DC power supply 520, faceplate 510 can be fixed to AC-DC power supply 520 by several ways, such as mechanical fixturing, adhesives, and the like. When the two are coupled together, faceplate 510 can enable line-break plunger 526 to enter an engaged position within AC-DC power supply 520. In the engaged position, line-break plunger 526 can close a circuit between AC mains and AC-DC power supply 520, meaning AC signals can travel through the system to power on various electronic and/or electromechanical components. Both faceplate 510 and AC-DC power supply 520 can be put into electrical box 530 to reside as an in-wall switch to control one or more loads.

It may be appreciated that one or more other faceplate designs can be implemented in system 501 in place of or in addition to a rocker, as shown by faceplate 510. Other designs include but are not limited to double rockers, microphones and/or speakers, cameras, touchscreens, switches, dimmers, motion sensors, or any combination thereof. When faceplate 510 is removed and/or replaced from AC-DC power supply 520, line-break plunger 526 is disengaged and opens the circuit between AC mains and the system, thus, removing any electrical touch risk from AC-DC power supply 520 to allow user manipulation of faceplate 510.

FIG. 5B includes system 502, which further includes faceplate front 505, faceplate back 510, AC-DC power supply 520, and electrical box 530. Faceplate front 505 embodies a touchscreen module. Faceplate 510 further includes low-voltage pins 512, DC pins 514, and control interface 516. AC-DC power supply 520 further includes low-voltage ports 522, DC ports 524, and line-break plunger 526.

System 502 illustrates a faceplate front 505 that is a capacitive touchscreen operatively coupled to AC-DC power supply 520, which is further coupled and fixed to electrical box 530. The faceplate can be operatively coupled with AC-DC power supply 520 via the pins located on faceplate back 510. Low-voltage pins 512 can comprise one or more inputs that can be connected to one or more ports of low-voltage ports 522. Likewise, DC pins 514 can be coupled with DC ports 524 to supply power to the faceplate. Control interface 516 can comprise various electronics to provide capabilities of the module, like touchscreen functions illustrated in faceplate front 505.

After coupling inputs of faceplate back 510 to ports of AC-DC power supply 520, the faceplate can be fixed to AC-DC power supply 520. When the two are coupled together, the faceplate enables line-break plunger 526 to enter an engaged position within AC-DC power supply 520. In the engaged position, line-break plunger 526 can close a circuit between AC mains and AC-DC power supply 520, meaning AC signals can travel through the system to power on various electronic components. Both faceplate 510 and AC-DC power supply 520 can be put into electrical box 530 to reside as an in-wall switch to control one or more loads, such as lighting, a furnace, one or more cameras or sensors, and the like.

It may be appreciated that one or more other faceplate designs can be implemented in system 502 in place of or in addition to a capacitive touchscreen, as shown by faceplate front 505. Other designs include but are not limited to rockers, double rockers, microphones and/or speakers, cameras, LED or LCD touchscreens, switches, dimmers, motion sensors, or any combination thereof.

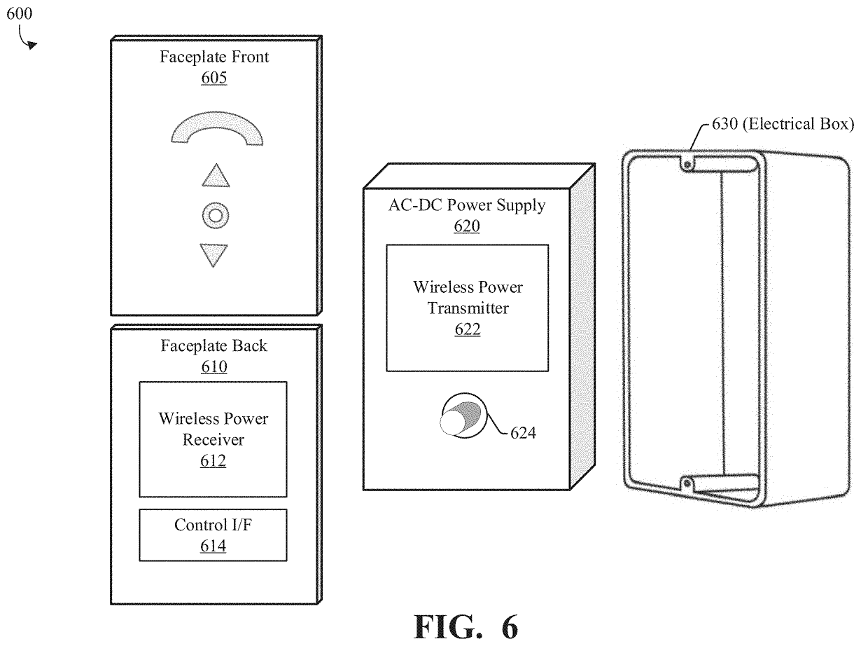

FIG. 6 illustrates another exemplary power supply and switch system enabling wireless power transfer from a power supply to a removable faceplate module. FIG. 6 includes system 600, which further includes faceplate front 605, faceplate back 610, AC-DC power supply 620, and electrical box 630. Faceplate 605 embodies a touchscreen module. Faceplate 610 further includes wireless power receiver 612 and control interface 614. AC-DC power supply 620 further includes wireless power transmitter 622 and line-break plunger 624.

Faceplate front 605 and faceplate back 610 demonstrate a removable module that can be powered by DC circuitry of AC-DC power supply 620. Faceplate front 605 provides a user interface to control the module. Faceplate back 610 provides a control interface to allow control of the module when powered by AC-DC power supply 620. Faceplate back 610 comprises a wireless power receiver 612 which can be operatively coupled with wireless power transmitter 622 to obtain power from AC-DC power supply 620. AC-DC power supply 620 can be connected to AC mains to provide power to wireless power transmitter 622, among other components. In various embodiments, upon transferring power from AC-DC power supply 620 to wireless power receiver 612, the faceplate module can receive DC power to control one or more aspects of the module via control interface 614. Control interface 614 can provide power commands, dimming commands, and other touchscreen functions, for example, among other capabilities.

Faceplate back 610 can be operatively coupled to AC-DC power supply 620 in a configuration wherein wireless power receiver 612 and wireless power transmitter 622 align in proximity to enable power transfer. In an unpaired state, no power is transmitted not only because the transmitter and receiver combination is not close enough, but also because line-break plunger 624 remains in a disengaged position, cutting any power from AC mains to AC-DC power supply 620. In some embodiments, line-break plunger 624 can be removed from AC-DC power supply 620 as AC-DC power supply 620 does not have an electrical touch risk or other dangerous features when the transmitter and receiver are not paired.

It may be appreciated that one or more other faceplate designs can be implemented in system 600 in place of or in addition to a capacitive touchscreen, as shown by faceplate front 605. Other designs include but are not limited to rockers, double rockers, microphones and/or speakers, cameras, LED or LCD touchscreens, switches, dimmers, motion sensors, or any combination thereof.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having operations, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for,” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

Disclosed herein are implementations using an in-wall power supply to control aspects of various modules.

In a first aspect, the subject matter described in this specification can be embodied in assemblies comprising: a power supply module comprising ac circuitry configured to at least convert an ac signal to a dc signal, an interface coupled with a removable module, and a logic circuit configured to at least control an aspect of an ac load based on an indication from one or more input devices of the removable module, and a removable module comprising the one or more input devices, dc circuitry fed by the dc signal of the power supply module to provide power to the removable module, and a communication interface configured to at least provide the indication from the one or more input devices to the logic circuit via the interface of the power supply module.

In a second aspect, the subject matter described in this specification can be embodied in assemblies that include the modular switch assembly of the preceding aspect, wherein the power supply module further comprises a line-break plunger actuated by the removable module, the line-break plunger configured to depress on contact by the removable module to engage the ac circuitry of the power supply module.

In a third aspect, the subject matter described in this specification can be embodied in assemblies that include the modular switch assembly of the preceding aspects, or any combination thereof, wherein the power supply module further comprises a power meter configured to at least monitor performance of at least the power supply module and the ac load.

In a fourth aspect, the subject matter described in this specification can be embodied in assemblies that include the modular switch assembly of the preceding aspects, or any combination thereof, wherein the interface coupled with the removable module is a wired connection between one or more dc inputs of the dc circuitry and one or more dc ports of the power supply module.

In a fifth aspect, the subject matter described in this specification can be embodied in assemblies that include the modular switch assembly of the preceding aspects, or any combination thereof, wherein the interface coupled with the removable module is a wireless coupling.

In a sixth aspect, the subject matter described in this specification can be embodied in assemblies that include the modular switch assembly of the preceding aspects, or any combination thereof, wherein the one or more input devices includes at least one among a dimmer, a sensor, a button, and a touchscreen.

In a seventh aspect, the subject matter described in this specification can be embodied in assemblies that include the modular switch assembly of the preceding aspects, or any combination thereof, wherein the dc signal generates 12V dc.

In an eighth aspect, the subject matter described in this specification can be embodied in devices including a power supply module comprising: an ac-to-dc transformer fed by an ac source and configured to convert the ac source to dc power, one or more dc ports fed by the dc power, a controller fed by the ac source and operatively coupled to an ac load, wherein the controller is configured to at least control an aspect of the ac load, and a line-break plunger configured to create one among an open circuit between the ac source and the power supply module and a closed circuit between the ac source and the power supply module.

In a ninth aspect, the subject matter described in this specification can be embodied in devices that include the power supply module of the preceding aspect, wherein the one or more dc ports and the controller of the power supply module are operatively coupled with a removable module.

In a tenth aspect, the subject matter described in this specification can be embodied in devices that include the power supply module of the preceding aspects, or any combination thereof, wherein the removable module, when in an affixed position, enables the line-break plunger to create the closed circuit and enables control of the aspect of the ac load.

In an eleventh aspect, the subject matter described in this specification can be embodied in devices that include the power supply module of the preceding aspects, or any combination thereof, wherein the removable module, when in a disconnected position, enables the line-break plunger to create the open circuit and disables control of the aspect of the ac load.

In a twelfth aspect, the subject matter described in this specification can be embodied in devices that include the power supply module of the preceding aspects, or any combination thereof, wherein the one or more dc ports comprise a 12-volt source and a reference line and are configured to supply the dc power to the removable module.

In a thirteenth aspect, the subject matter described in this specification can be embodied in devices that include the power supply module of the preceding aspects, or any combination thereof, wherein the controller comprises at least one among a dimmer control port and a communication control port.

In a fourteenth aspect, the subject matter described in this specification can be embodied in devices that include the power supply module of the preceding aspects, or any combination thereof, wherein the controller is further configured to monitor performance of at least the power supply module and the ac load.

In a fifteenth aspect, the subject matter described in this specification can be embodied in systems that include a power supply module and a removable module comprising: a power supply module including one or more dc ports, a controller, an ac-dc transformer, and a line-break plunger, wherein the ac-dc transformer is fed by an ac line and is configured to convert ac power of the ac line to dc power for use by the one or more dc ports; and a removable module operatively coupled with the one or more dc ports and the controller of the power supply module, wherein responsive to coupling the removable module with the one or more dc ports and the controller, the line-break plunger enables a connection between the ac line and the power supply module.

In a sixteenth aspect, the subject matter described in this specification can be embodied in systems that include the power supply module and the removable module of the preceding aspect, wherein the power supply module is further coupled with an ac load.

In a seventeenth aspect, the subject matter described in this specification can be embodied in systems that include the power supply module and the removable module of the preceding aspects, or any combination thereof, wherein the removable module is configured to control at least an aspect of the ac load using the controller.

In an eighteenth aspect, the subject matter described in this specification can be embodied in systems that include the power supply module and the removable module of the preceding aspects, or any combination thereof, wherein the one or more dc ports comprise a 12-volt line and a reference line.

In a nineteenth aspect, the subject matter described in this specification can be embodied in systems that include the power supply module and the removable module of the preceding aspects, or any combination thereof, wherein, responsive to decoupling the removable module from the one or more dc ports and the controller, the line-break plunger breaks the connection between the ac source and the power supply module.

In a twentieth aspect, the subject matter described in this specification can be embodied in systems that include the power supply module and the removable module of the preceding aspects, or any combination thereof, wherein the removable module is at least one among a smart switch, a thermostat, a lighting control switch, and a touchscreen.

What is claimed is:

1. A modular switch assembly, comprising:
a power supply module comprising:
ac circuitry configured to at least convert an ac signal to a dc signal;
an interface coupled with a removable module; and
a logic circuit configured to at least control an aspect of an ac load based on an indication from one or more input devices of the removable module;
the removable module comprising:
the one or more input devices;
dc circuitry fed by the dc signal of the power supply module to provide power to the removable module; and
a communication interface configured to at least provide the indication from the one or more input devices to the logic circuit via the interface of the power supply module.

2. The modular switch assembly of claim 1, wherein the power supply module further comprises a line-break plunger actuated by the removable module, the line-break plunger configured to depress on contact by the removable module to engage the ac circuitry of the power supply module.

3. The modular switch assembly of claim 1, wherein the power supply module further comprises a power meter configured to at least monitor performance of at least the power supply module and the ac load.

4. The modular switch assembly of claim 1, wherein the interface coupled with the removable module is a wired connection between one or more dc inputs of the dc circuitry and one or more dc ports of the power supply module.

5. The modular switch assembly of claim 1, wherein the interface coupled with the removable module is a wireless coupling.

6. The modular switch assembly of claim 1, wherein the one or more input devices includes at least one among a dimmer, a sensor, a button, a microphone, and a touch interface.

7. The modular switch assembly of claim 1, wherein the dc signal generates 12V dc.

8. A power supply module, comprising:
an ac-to-dc transformer fed by an ac source and configured to convert the ac source to dc power;
one or more dc ports fed by the dc power;
a controller fed by the ac source and operatively coupled to an ac load, wherein the controller is configured to at least control an aspect of the ac load; and
a line-break plunger configured to create one among an open circuit between the ac source and the power supply module and a closed circuit between the ac source and the power supply module.

9. The power supply module of claim 8, wherein the one or more dc ports and the controller of the power supply module are operatively coupled with a removable module.

10. The power supply module of claim 9, wherein the removable module, when in an affixed position, enables the line-break plunger to create the closed circuit and enables control of the aspect of the ac load.

11. The power supply module of claim 9, wherein the removable module, when in a disconnected position, enables the line-break plunger to create the open circuit and disables control of the aspect of the ac load.

12. The power supply module of claim 9, wherein the one or more dc ports comprise a 12- volt source and a reference line and are configured to supply the dc power to the removable module.

13. The power supply module of claim 8, wherein the controller comprises at least one among a dimmer control port and a communication control port.

14. The power supply module of claim 8, wherein the controller is further configured to monitor performance of at least the power supply module and the ac load.

15. A system, comprising:
a power supply module including one or more dc ports, a controller, an ac-dc transformer, and a line-break plunger, wherein the ac-dc transformer is fed by an ac source and is configured to convert ac power of the ac source to dc power for use by the one or more dc ports; and
a removable module operatively coupled with the one or more dc ports and the controller of the power supply module, wherein responsive to coupling the removable module with the one or more dc ports and the controller, the line-break plunger enables a connection between the ac source and the power supply module.

16. The system of claim 15, wherein the power supply module is further coupled with an ac load.

17. The system of claim 16, wherein the removable module is configured to control at least an aspect of the ac load using the controller.

18. The system of claim 15, wherein the one or more dc ports comprise a 12-volt source and a reference line.

19. The system of claim 15, wherein, responsive to decoupling the removable module from the one or more dc ports and the controller, the line-break plunger breaks the connection between the ac source and the power supply module.

20. The system of claim 15, wherein the removable module is at least one among a smart switch, a thermostat, a lighting control switch, and a touchscreen.
